(19) United States
(12) Patent Application Publication
(10) Pub. No.: US 2024/0332865 A1
(43) Pub. Date: Oct. 3, 2024

(54) COOLING DEVICE

(71) Applicant: Nidec Corporation, Kyoto (JP)

(72) Inventors: Keisuke KAWATA, Kyoto (JP); Toshihiko TOKESHI, Kyoto (JP); Takehito TAMAOKA, Kyoto (JP)

(21) Appl. No.: 18/614,783

(22) Filed: Mar. 25, 2024

(30) Foreign Application Priority Data
Mar. 30, 2023 (JP) 2023-055583

(51) Int. Cl. H01R 13/6581; H05K 7/20

(52) U.S. Cl. CPC H01R 13/6581; H05K 7/20154; H05K 7/20245

(57) ABSTRACT

A cooling device includes a first component, a second component, and a shielding portion. The first component cools a heat generating component. The second component is different from the first component. The shielding portion performs shielding between the first component and the second component. The shielding portion includes a conductive material.

### CROSS-REFERENCE TO RELATED APPLICATIONS

The present application claims priority under 35 U.S.C. § 119 to Japanese Patent Application No. 2023-055583, filed on Mar. 30, 2023, the entire contents of which are hereby incorporated herein by reference.

### 1. FIELD OF THE INVENTION

The present invention relates to a cooling device.

### 2. BACKGROUND

A conventional composite housing includes a primary composite housing and a coating film. The primary composite housing is formed of a metal plate having an electromagnetic wave shielding effect. The primary composite housing accommodates an electronic component that is a heat generating component in the inside. The coating film is a thin film of a heat dissipation material. The coating film is formed as a surface of the primary composite housing is coated with a heat dissipation material.

However, the conventional composite housing covers an outer periphery of an electronic component. In a case where the composite housing includes a plurality of components, an electromagnetic wave entering through a gap between one component and another component may affect the electronic component.

### SUMMARY

An example embodiment of a cooling device of the present disclosure includes a first component, a second component, and a shielding portion. The first component performs cooling of a heat generating component. The second component is different from the first component. The shielding portion performs shielding between the first component and the second component. The shielding portion includes a conductive material.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a diagram of a cooling device according to an example embodiment of the present disclosure.

FIG. 2 is a diagram in which a housing is omitted from the cooling device illustrated in FIG. 1.

FIG. 3 is a plan view of the cooling device illustrated in FIG. 2.

FIG. 4 is a side view of the cooling device illustrated in FIG. 2.

FIG. 5 is a perspective view illustrating a radiator according to an example embodiment of the present disclosure.

FIG. 6 is a side view of the radiator.

FIG. 7 is a perspective view illustrating a storage.

FIG. 8 is a front view illustrating a shielding portion attached to the radiator.

FIG. 9 is a diagram illustrating a cross section of the shielding portion.

FIG. 10 is a diagram illustrating a cross section taken along line X-X in FIG. 8.

FIG. 11 is a diagram illustrating an internal flow path of an accommodation portion according to an example embodiment of the present disclosure.

FIG. 12 is a perspective view illustrating a connection portion on the cold plate side of the radiator.

FIG. 13 is a diagram illustrating an internal flow path of the radiator.

FIG. 14 is a perspective view illustrating an internal flow path of the storage.

FIG. 15 is a diagram illustrating an internal flow path of the accommodation portion.

FIG. 16 is a diagram illustrating a cross section taken along line XVI-XVI in FIG. 12.

FIG. 17 is another diagram illustrating a shielding portion according to a first variation of an example embodiment of the present disclosure.

### DETAILED DESCRIPTION

Hereinafter, example embodiments of the present disclosure will be described with reference to the drawings. Note that in the drawings, the same or corresponding parts will be denoted by the same reference signs and description of such parts will not be repeated. In the specification of the present application, an X axis, a Y axis, and a Z axis that are orthogonal to each other may be described in order to facilitate the understanding of the disclosure. Although typically, the Z axis is parallel to a vertical direction, and the X axis and the Y axis are parallel to a horizontal direction, orientations of the X axis, the Y axis, and the Z axis are not limited to these.

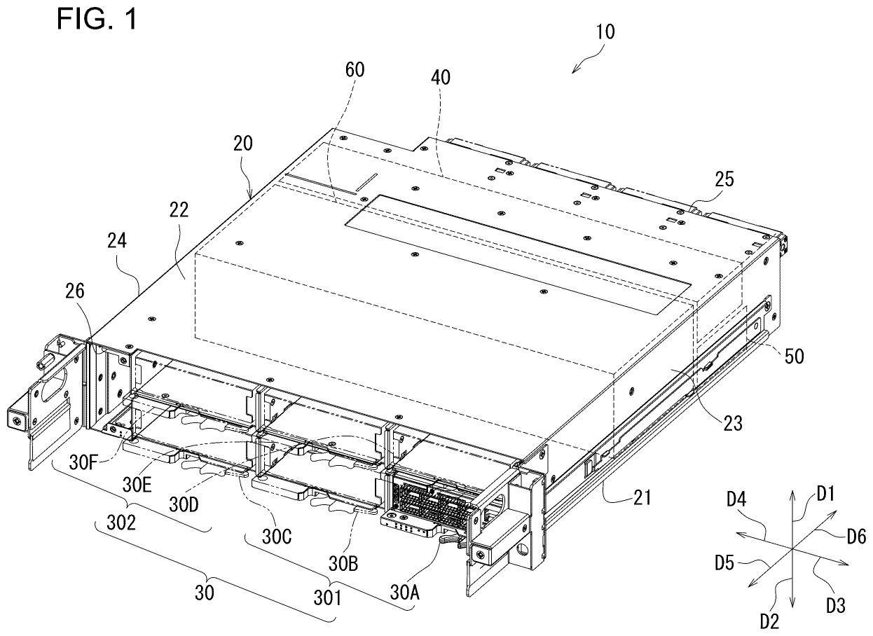

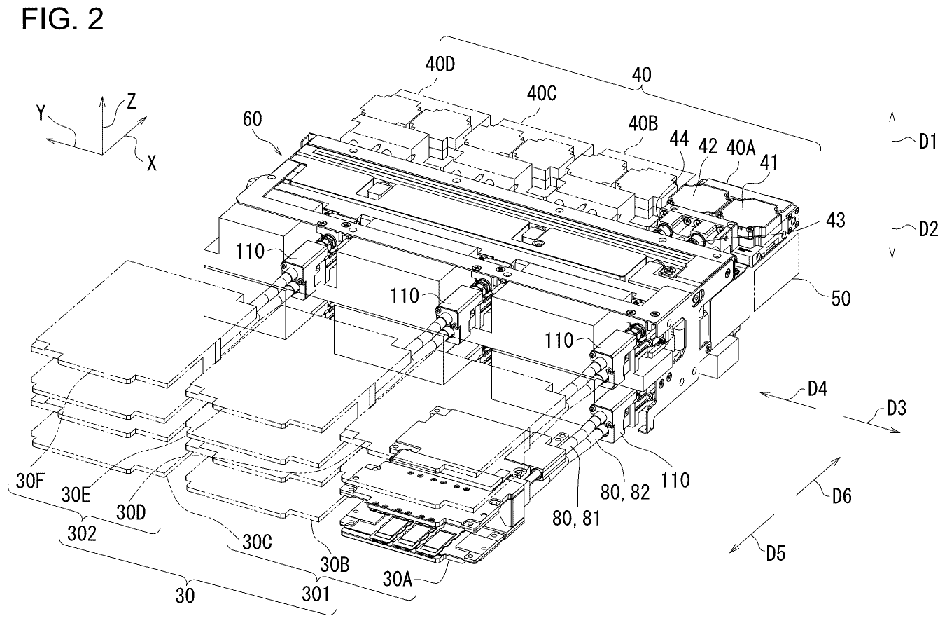

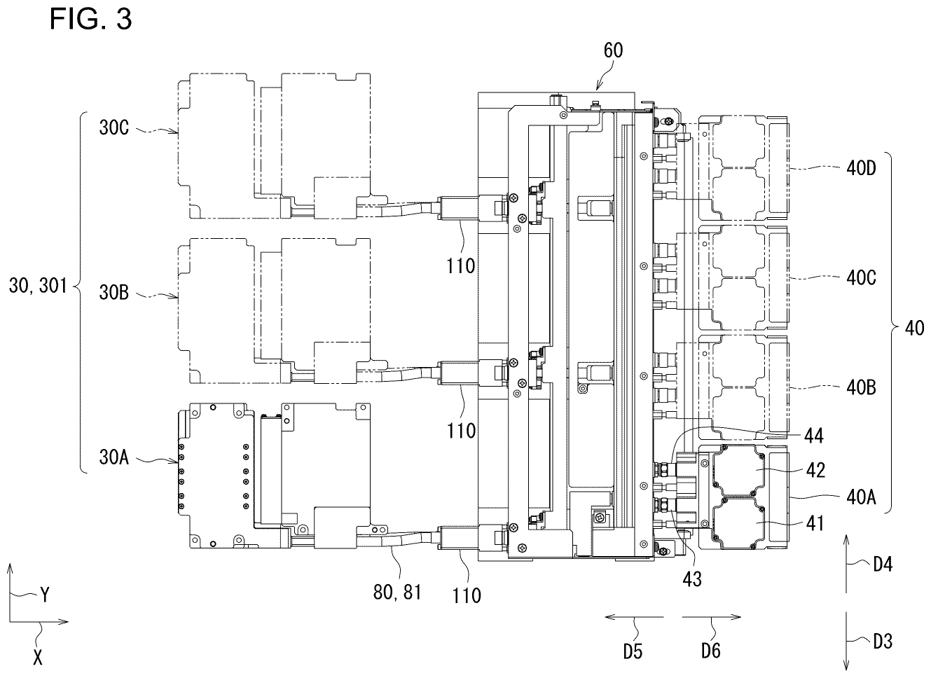

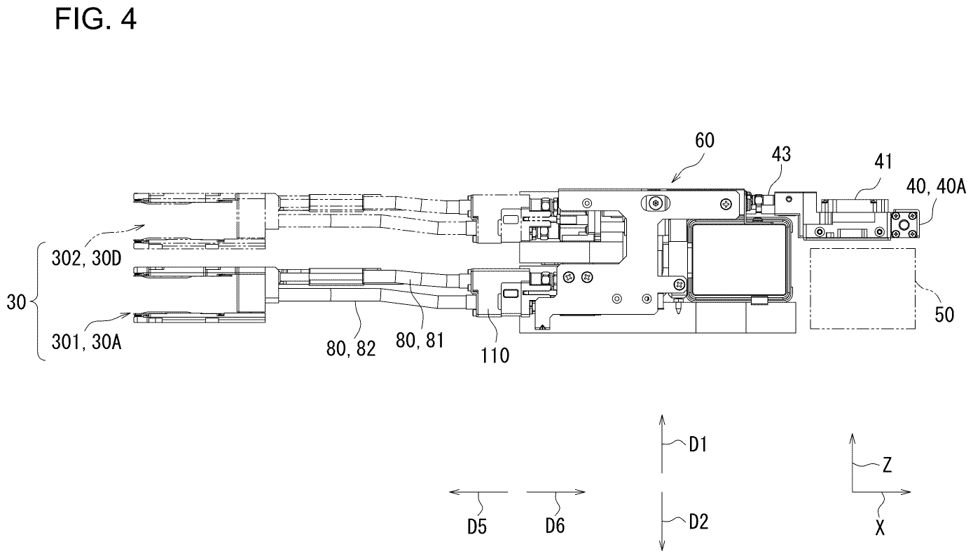

First, a cooling device 10 according to an first example embodiment will be described with reference to FIGS. 1 to 4. FIG. 1 is a diagram of the cooling device 10. FIG. 2 is a diagram in which a housing is omitted from the cooling device 10. FIG. 3 is a plan view of the cooling device 10 illustrated in FIG. 2. FIG. 4 is a side view of the cooling device 10 illustrated in FIG. 2. The cooling device 10 is used for cooling a heat generating component of a target device. For example, the cooling device 10 may cool a heat generating component of an electronic device. The heat generating component is, for example, a circuit of an electronic device. Further, for example, the heat generating component is a light source of an electronic device. Note that the electronic device may be any of a server, a projector, a notebook personal computer, and a two-dimensional display device.

As illustrated in FIG. 1, the cooling device 10 includes a housing 20, a cold plate 30, a liquid feeding device 40, a blowing device 50, and a radiator 60. The cold plate 30 corresponds to an example of a “cooling assembly”. The liquid feeding device 40 corresponds to an example of a “liquid feeding assembly”. The blowing device 50 corresponds to an example of a “blowing assembly”. The radiator 60 corresponds to an example of a “heat exchanger”.

The cooling device 10 circulates liquid as a refrigerant. AS the liquid feeding device 40 sequentially feeds liquid, the liquid circulates in the cooling device 10. In the cooling device 10, circulating liquid may be water. Alternatively, the circulating liquid may be mixed liquid. For example, the mixed liquid may contain water and propylene glycol. Further, the refrigerant is not limited to liquid. The refrigerant may be gas.

The housing 20 accommodates at least a part of the cold plate 30, the liquid feeding device 40, the blowing device 50, and the radiator 60. In other words, the housing 20 surrounds the liquid feeding device 40, the blowing device 50, and the radiator 60. The housing 20 is made of, for example, metal. As illustrated in FIG. 1, the housing 20 has, for example, a rectangular parallelepiped shape. Specifically, the housing 20 has a first surface 21, a second surface 22, a third surface 23, a fourth surface 24, and a fifth surface 25.

The first surface 21 constitutes, for example, a bottom surface. The first surface 21 faces the second surface 22 in a first direction D1. The first direction D1 indicates a direction from the first surface 21 toward the second surface 22. Further, the second surface 22 constitutes, for example, a top surface. The second surface 22 faces the first surface 21. The second surface 22 is located further in the first direction D1 than the first surface 21. The first direction D1 indicates a direction opposite to a second direction D2. The second direction D2 is along a direction in which gravity acts. The first surface 21 supports the cold plate 30, the liquid feeding device 40, the blowing device 50, and the radiator 60. A Z-axis direction includes the first direction D1 and the second direction D2. The Z-axis direction corresponds to an example of a “first direction”. Note that the first surface 21 corresponds to an example of a “second component S2”.

The third surface 23 and the fourth surface 24 constitute, for example, side surfaces. The third surface 23 and the fourth surface 24 are located between the first surface 21 and the second surface 22. The third surface 23 and the fourth surface 24 extend along the first direction D1 and the second direction D2. The third surface 23 faces the fourth surface 24 in a third direction D3. The third direction D3 indicates a direction from the third surface 23 toward the fourth surface 24. A fourth direction D4 indicates a direction opposite to the third direction D3, and indicates a direction from the third surface 23 toward the fourth surface 24. A Y-axis direction includes the third direction D3 and the fourth direction D4. The Y-axis direction corresponds to an example of a “second direction”.

The fifth surface 25 constitutes, for example, a back surface. The fifth surface 25 is located between the first surface 21 and the second surface 22, and is located between the third surface 23 and the fourth surface 24. The fifth surface 25 extends along the first direction D1 and the second direction D2, and extends along the third direction D3 and the fourth direction D4. The fifth surface 25 faces the liquid feeding device 40 in a fifth direction D5. The fifth direction D5 indicates a direction from the fifth surface 25 toward the cold plate 30. A sixth direction D6 indicates a direction opposite to the fifth direction D5, and indicates a direction from the cold plate 30 toward the fifth surface 25. An X-axis direction includes the fifth direction D5 and the sixth direction D6. The X-axis direction corresponds to an example of a “third direction”.

The housing 20 has an open end portion on the fifth direction D5 side facing the fifth surface 25. The housing 20 has an opening 26 at an end portion on the fifth direction D5 side. From the opening 26, the cold plate 30 partially protrudes in the fifth direction D5.

The cold plate 30 absorbs heat of a heat source of a target device. The cold plate 30 accommodates liquid in the inside. The cold plate 30 cools a heat generating component with liquid. The cold plate 30 is arranged in the fifth direction D5 with respect to the radiator 60. The cold plate 30 is made from metal having high thermal conductivity such as copper or aluminum. The cold plate 30 is a rectangular plate component extending in the X-axis direction and the Y-axis direction. Note that the shape of the cold plate 30 may be other than a rectangular shape.

Specifically, the cold plate 30 conducts heat of a heat generating component as a heat source to liquid. For this reason, the cold plate 30 is arranged near a heat generating component. For example, the cold plate 30 is arranged to face a heat source. Alternatively, the cold plate 30 may be arranged in contact with a heat source. In a case where the cold plate 30 is arranged to face a heat source, the cold plate 30 faces the heat source with a transmission member interposed between them. The transmission member is, for example, heat grease. The heat grease enters a minute gap between the cold plate 30 and a heat source. This reduces a gap between the cold plate 30 and the heat source. As a result, thermal conductivity from a heat source to the cold plate 30 is improved.

As illustrated in FIGS. 1 to 4, the cold plate 30 includes a plurality of cold plates. Specifically, the cold plate 30 includes a first cold plate 30A, a second cold plate 30B, a third cold plate 30C, a fourth cold plate 30D, a fifth cold plate 30E, and a sixth cold plate 30F. The cold plate 30 is divided into first set cold plates 301 and second set cold plates 302. The first set cold plates 301 include the first cold plate 30A, the second cold plate 30B, and the third cold plate 30C. The second set cold plates 302 include the fourth cold plate 30D, the fifth cold plate 30E, and the sixth cold plate 30F. Cold plates of the first set cold plates 301 are adjacent to each other in a direction along the third direction D3 and the fourth direction D4. Cold plates of the second set cold plates 302 are adjacent to each other in a direction along the third direction D3 and the fourth direction D4. Further, the first set cold plates 301 face the second set cold plates 302 in the first direction D1. Since the first cold plate 30A to the sixth cold plate 30F have the same structure, the first cold plate 30A to the sixth cold plate 30F will be collectively referred to as the cold plate 30 unless otherwise specified.

The liquid feeding device 40 causes liquid to flow. The liquid feeding device 40 circulates liquid through the cold plate 30 and the radiator 60. The liquid feeding device 40 is connected to the radiator 60. To the liquid feeding device 40, liquid heat-exchanged by the radiator 60 is returned. Liquid fed from the liquid feeding device 40 flows toward the cold plate 30. Then, the liquid flows from the cold plate 30 toward the radiator 60. Note that the liquid feeding device 40 is not limited to being directly connected to the radiator 60. The liquid feeding device 40 includes being connected to the radiator 60 via another component such as a pipe.

The liquid feeding device 40 includes a plurality of liquid feeding devices. Specifically, as illustrated in FIGS. 2 and 3, the liquid feeding device 40 includes a first liquid feeding device 40A, a second liquid feeding device 40B, a third liquid feeding device 40C, and a fourth liquid feeding device 40D. The first liquid feeding device 40A to the fourth liquid feeding device 40D are adjacent to each other in a direction along the third direction D3 and the fourth direction D4. Each of the first liquid feeding device 40A to the fourth liquid feeding device 40D is connected to the radiator 60. Further, each of the first liquid feeding device 40A to the fourth liquid feeding device 40D communicates with the cold plate 30 via the radiator 60. Each of the first liquid feeding device 40A to the fourth liquid feeding device 40D includes a first pump 41 and a second pump 42. Since the first liquid feeding device 40A to the fourth liquid feeding device 40D have the same structure, unless otherwise specified, the first liquid feeding device 40A to the fourth liquid feeding device 40D will be collectively described using the liquid feeding device 40.

The first pump 41 sends liquid to a first coupling portion 43. The first pump 41 includes a casing, an impeller (not illustrated), a pump rotation shaft (not illustrated), and a motor (not illustrated). The impeller (not illustrated) is supported by the pump rotation shaft (not illustrated), and when the pump rotation shaft (not illustrated) rotates about an axis, the impeller (not illustrated) rotates. The motor rotates the impeller (not illustrated) about the pump rotation shaft (not illustrated).

The second pump 42 sends liquid flowing in from a second coupling portion 44 to the first pump 41. The second pump 42 includes a casing, an impeller (not illustrated), a pump rotation shaft (not illustrated), and a motor (not illustrated). The impeller (not illustrated) is supported by the pump rotation shaft (not illustrated), and when the pump rotation shaft (not illustrated) rotates about an axis, the impeller (not illustrated) rotates. The motor rotates the impeller (not illustrated) about the pump rotation shaft (not illustrated).

The first pump 41 and the second pump 42 are adjacent to each other in a direction along the third direction D3 and the fourth direction D4. The first pump 41 faces the second pump 42 in the fourth direction D4. The first pump 41 and the second pump 42 are connected in series by an internal flow path (not illustrated). Note that the first pump 41 and the second pump 42 are not limited to being connected in series. The first pump 41 and the second pump 42 may be connected in parallel.

The blowing device 50 sends air. The blowing device 50 blows air in the fifth direction D5. As illustrated in FIGS. 2 and 4, the blowing device 50 faces the radiator 60 in the fifth direction D5. That is, the blowing device 50 sends air to the radiator 60. The blowing device 50 is, for example, a blower fan of an axial flow type. In the blowing device 50, a plurality of blower fans may be arranged to face the radiator 60. Further, in the blowing device 50, a single blower fan may be arranged to face the radiator 60. Further, the blowing device 50 faces the liquid feeding device 40 in the first direction D1. The blowing device 50 is arranged in a space formed by the liquid feeding device 40 and the radiator 60. Therefore, for the blowing device 50, a space formed by the liquid feeding device 40 and the radiator 60 can be used as an arrangement space. As a result, the cooling device 10 can be downsized. Further, since the blowing device 50 is sandwiched between the liquid feeding device 40 and the first surface 21, air is not released in the first direction D1 and the second direction D2. Therefore, the blowing device 50 can intensively send air to the radiator 60.

The radiator 60 releases heat of liquid flowing through a pipe 80 to the outside. As illustrated in FIGS. 2 to 4, the radiator 60 is connected to the cold plate 30 via the pipe 80. Heat of a heat source is transferred through the cold plate 30 and absorbed by liquid in the inside. After the above, liquid passing through the cold plate 30 returns to the radiator 60, and the radiator 60 releases heat to the outside, so that the liquid is cooled. Then, the cooled liquid is sent again to the pipe 80 by the liquid feeding device 40. The radiator 60 corresponds to an example of a “first component S1”. The radiator 60 is a component related to cooling of a heat generating component.

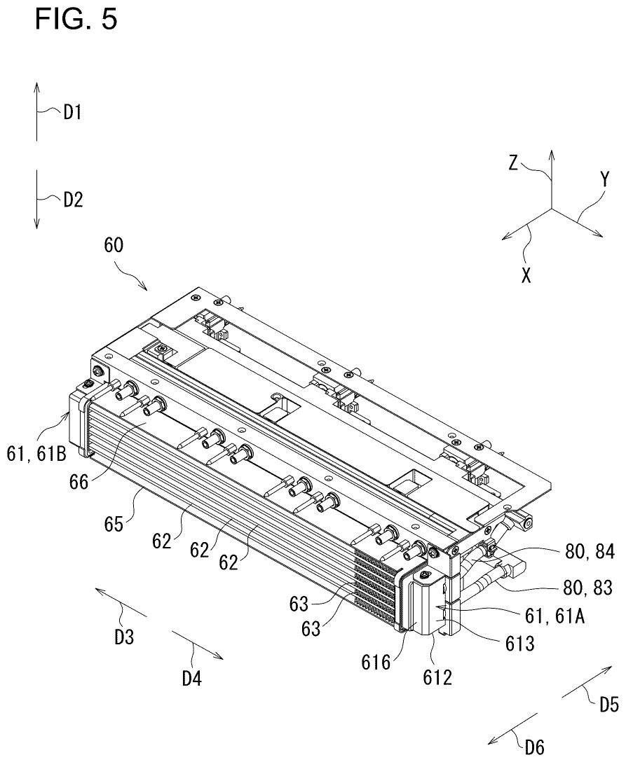

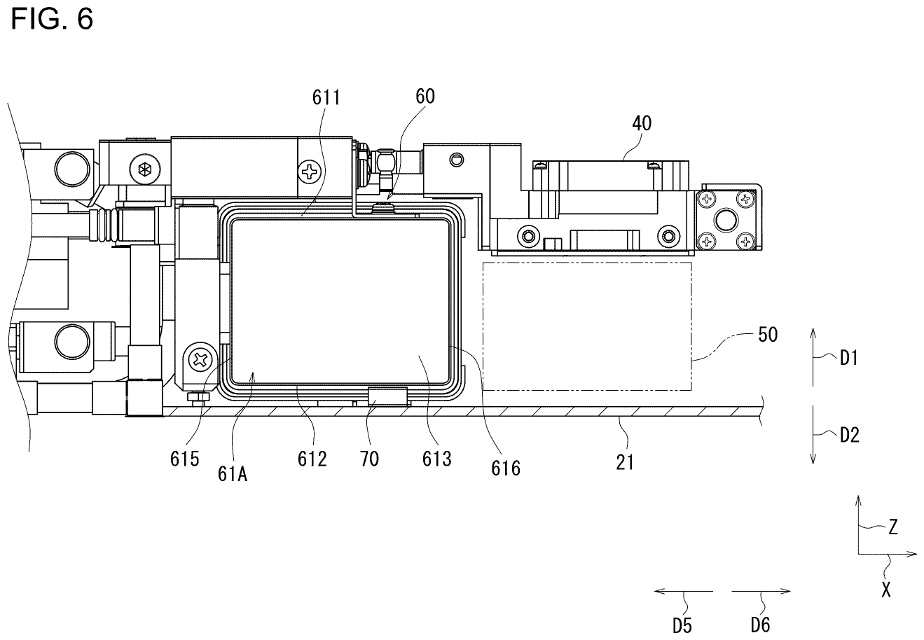

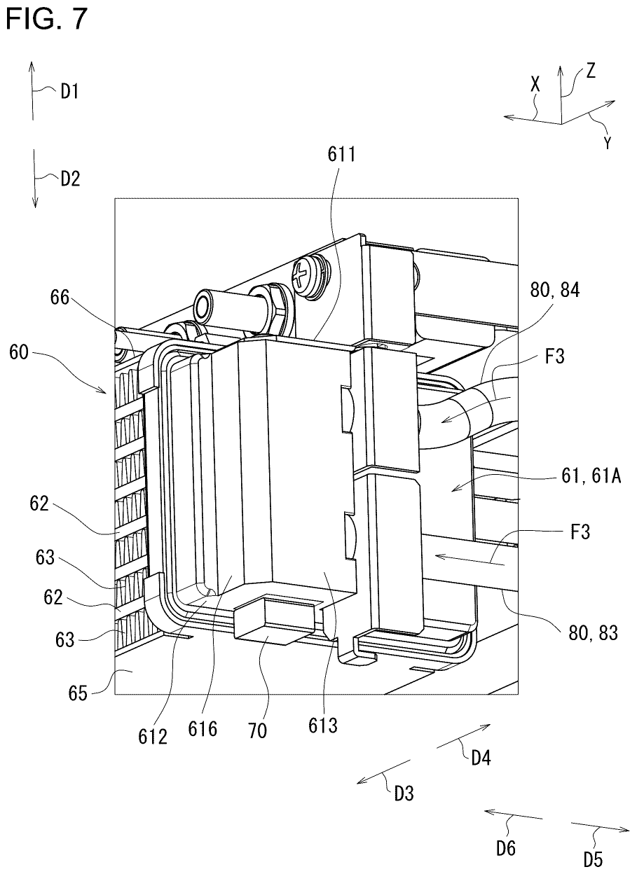

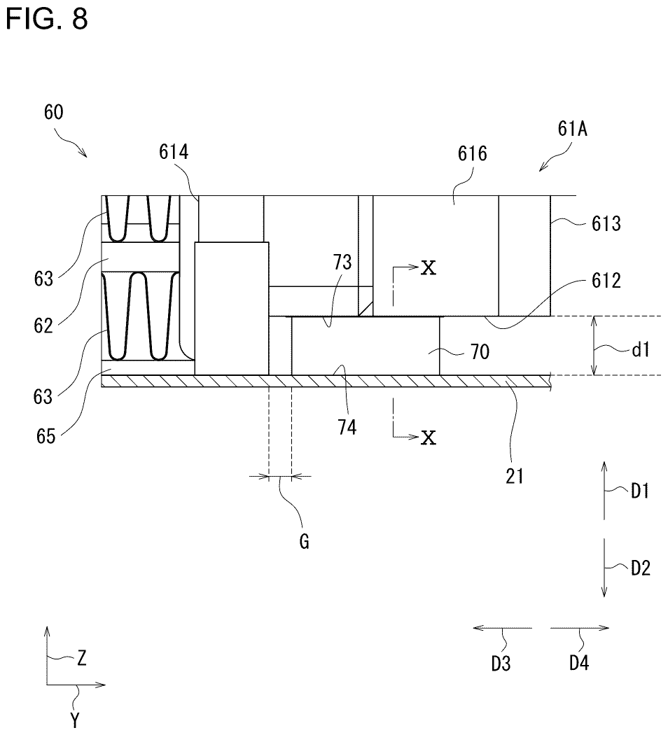

The radiator 60 will be described in detail with reference to FIGS. 5 to 8. FIG. 5 is a perspective view illustrating the radiator 60. FIG. 6 is a side view of the radiator 60. FIG. 7 is a perspective view illustrating a storage. FIG. 8 is a front view illustrating a shielding portion 70 attached to the radiator 60.

As illustrated in FIGS. 5 to 8, the radiator 60 includes a storage 61, a pipe 62, a fin 63, and the shielding portion 70. The radiator 60 may have a plurality of the storages 61. For example, the radiator 60 may have a pair of the storages 61. Further, the radiator 60 may have a plurality of the pipes 62.

The storage 61 stores a refrigerant. The storage 61 is formed of a conductive material. Specifically, the storage 61 is made from conductive metal. The storage 61 is a rectangular parallelepiped hollow component. Note that the shape of the storage 61 may be a shape other than a rectangular parallelepiped shape. The storage 61 includes a storage 61A and a storage 61B. Note that a refrigerant is not limited to liquid. The refrigerant may be gas.

The storage 61A faces the storage 61B in the third direction D3. The storage 61A stores liquid sent from the cold plate 30. Then, the storage 61A sends the liquid to the storage 61B via the pipe 62.

The storage 61A includes a top surface portion 611, a bottom surface portion 612, an outer surface portion 613, an inner surface portion 614, a front surface portion 615, and a back surface portion 616. The top surface portion 611 is a rectangular plate component extending in the X-axis direction and the Y-axis direction. The bottom surface portion 612 faces the top surface portion 611 in the first direction D1. Therefore, in other words, the bottom surface portion 612 faces the top surface portion 611 in the first direction. As illustrated in FIG. 8, the bottom surface portion 612 is arranged away from the first surface 21 by a length d1 in the first direction D1. The outer surface portion 613 and the inner surface portion 614 constitute side surfaces intersecting the third direction D3 and the fourth direction D4. The inner surface portion 614 is longer than the outer surface portion 613 in the second direction D2. The inner surface portion 614 has an end portion in the second direction D2 in contact with the first surface 21. The front surface portion 615 and the back surface portion 616 constitute side surfaces intersecting the fifth direction D5 and the sixth direction D6.

As illustrated in FIG. 5, the storage 61B stores liquid sent from the storage 61A. Then, the storage 61B sends liquid to the liquid feeding device 40. Note that, in the storage 61B, a configuration other than an internal flow path is the same as the configuration of the storage 61A, and thus will be omitted from description.

Liquid flows through the pipe 62. The pipe 62 allows liquid to flow from the storage 61A to the storage 61B. The pipe 62 extends in a direction along the third direction D3 and the fourth direction D4. A cross section of the pipe 62 is formed in a flat shape having a minor axis in the first direction D1 and the second direction D2 and a major axis in the fifth direction D5 and the sixth direction D6. A plurality of the pipes 62 are provided. The pipe 62 is arranged apart from an adjacent one of the pipes 62 in the Z-axis direction by a predetermined distance. As illustrated in FIG. 5, the pipe 62 is arranged between a bottom plate 65 and a top plate 66.

The bottom plate 65 and the top plate 66 extend along the third direction D3 and the fourth direction D4. The top plate 66 is located further in the first direction D1 than the pipe 62 located furthest in the first direction D1. The bottom plate 65 is located further in the second direction D2 than the pipe 62 located furthest in the second direction D2. The bottom plate 65 is in contact with the first surface 21, for example. However, the bottom plate 65 is not limited to being in contact with the first surface 21. The bottom plate 65 may be slightly separated from the first surface 21.

The fin 63 causes heat to be exchanged between liquid flowing in the pipe 62 and outside air. A plurality of the fins 63 may be provided. The fins 63 are arranged, for example, between the pipe 62 and the pipe 62, between the pipe 62 and the bottom plate 65, and between the pipe 62 and the top plate 66. A longitudinal direction of the fin 63 extends along the third direction D3 and the fourth direction D4. A lateral direction of the fin 63 extends along the fifth direction D5 and the sixth direction D6. The fin 63 has an end portion on the first direction D1 side in contact with the pipe 62 located on the first direction D1 side with respect to the fin 63. The fin 63 has an end portion on the second direction D2 side in contact with the pipe 62 on the second direction D2 side with respect to the fin 63. The pipe 62 is welded at a contact portion between the pipe 62 and the fin 63. The fin 63 is made from metal that has high thermal conductivity.

As illustrated in FIGS. 6 to 8, the shielding portion 70 is a shielding member that blocks intrusion of an electromagnetic wave. The shielding portion 70 contains a conductive material. The conductive material includes, for example, an electromagnetic wave shielding material such as copper, aluminum, nickel, or iron. Then, the shielding portion 70 has, for example, a reflection loss function. However, the function of the shielding portion 70 is not limited to a reflection loss function. The shielding portion 70 only needs to be able to block at least intrusion of an electromagnetic wave, and may have an absorption loss function or a multiple reflection loss function. Further, the shielding portion 70 may have a reflection loss function, an absorption loss function, or a multiple reflection loss function in combination. The reflection loss function is a function of causing loss of a transmitted electromagnetic wave at a boundary surface between a shielding member and air. The absorption loss function is a function of causing loss of an electromagnetic wave by overcurrent generated when passing through a shielding member. The multiple reflection loss function is a function of causing loss of an electromagnetic wave by repeatedly generating reflection in a shielding member.

The shielding portion 70 performs shielding between the first component S1 and the second component S2. The second component S2 is different from the first component S1. That is, the first component S1 related to cooling and the first component S1 are different components. The shielding portion 70 blocks a space between the first component S1 and the second component S2 even if there is a gap between the first component S1 and the second component S2.

As described above, since the shielding portion 70 contains a conductive material, it is possible to block an electromagnetic wave that enters from the outside by passing between the first component S1 and the second component S2 and. As a result, the shielding portion 70 can reduce influence of an electromagnetic wave on a heat generating component of an electronic device. Further, the shielding portion 70 is a conductive member containing a conductive material, and has a reflection loss function. Therefore, the shielding portion 70 can conduct to another component such as the housing 20 or the storage 61. As a result, even if a minute gap is formed between the shielding portion 70 and another component, the gap can be shielded, and influence of an electromagnetic wave can be reduced.

For example, in a case where the first component S1 is the radiator 60 and the second component S2 is the housing 20, the shielding portion 70 shields a space between the radiator 60 and the housing 20. It is possible to block an electromagnetic wave entering from the outside by passing between the radiator 60 and the housing 20. Specifically, as illustrated in FIGS. 6 to 8, the shielding portion 70 shields a space between the bottom surface portion 612 and the first surface 21. The shielding portion 70 blocks an electromagnetic wave that enters from the outside by passing between the bottom surface portion 612 and the first surface 21. That is, the shielding portion 70 containing a conductive material is arranged between the radiator 60 and the housing 20 with the conductive material being in contact with both the radiator 60 and the housing 20, so that the housing 20 and the radiator 60 function as one conductive material, and influence of an electromagnetic wave on a component arranged in a space surrounded by both the radiator 60 and the housing 20 is reduced. Note that, in the present description, “to block” or “to perform shielding” does not mean “to shield and cover from, or to cover and prevent from being seen from others”, but means to play a role of electromagnetic shielding. The shielding portion 70 does not need to cover an arranged member or prevent an arranged member from being seen from others.

As illustrated in FIGS. 2 and 3, the cold plate 30 is arranged on one side in the X-axis direction with respect to the radiator 60. Therefore, the shielding portion 70 can reduce an electromagnetic wave entering the radiator 60 from the other side in the third direction. As a result, the shielding portion 70 can cool a heat generating component of an electronic device while avoiding influence of an electromagnetic wave.

Moreover, the blowing device 50 is arranged on the other side in the X-axis direction with respect to the radiator 60. Therefore, the shielding portion 70 can prevent wind of the blowing device 50 from escaping in a direction other than the radiator 60. As a result, the shielding portion 70 can enhance cooling performance of the radiator 60.

Furthermore, the liquid feeding device 40 is arranged on the other side in the X-axis direction with respect to the radiator 60. Therefore, the shielding portion 70 can block an electromagnetic wave caused by the liquid feeding device 40. That is, the shielding portion 70 prevents an electromagnetic wave of the liquid feeding device 40 from passing between the radiator 60 and the housing 20. As a result, shielding property for an electronic device can be enhanced.

As illustrated in FIGS. 6 and 8, the shielding portion 70 performs shielding between the storage 61 and the first surface 21. Therefore, the shielding portion 70 can block an electromagnetic wave entering from between the storage 61 and the first surface 21. Therefore, in the cooling device 10 using the radiator 60, the shielding portion 70 can reduce influence of an electromagnetic wave. Further, cooling air passing through between the radiator 60 and the first surface 21 can be reduced. Therefore, in the cooling device 10 using the radiator 60, the shielding portion 70 can enhance a cooling effect. As a result, the shielding portion 70 can ensure shielding property against an electromagnetic wave and cooling property.

The housing 20 is not related to cooling of a heat generating component. That is, the housing 20 is the second component S2 different from the first component S1. Thus, the second component S2 includes the housing 20. As illustrated in FIGS. 6 and 8, the radiator 60 faces the first surface 21 in the second direction D2. That is, the shielding portion 70 performs shielding between the radiator 60 and the first surface 21 facing the radiator 60 in the X axis direction. Further, the X-axis direction indicates a direction in which the first surface 21 and the second surface 22 face each other. Therefore, the shielding portion 70 can block an electromagnetic wave entering from between the radiator 60 and the housing 20. As a result, in the cooling device 10 using the radiator 60 accommodated in the housing 20, the shielding portion 70 can reduce influence of an electromagnetic wave. Note that, in a case where the radiator 60 faces the second surface 22, the shielding portion 70 may perform shielding between the radiator 60 and the second surface 22 facing the radiator 60 in the X-axis direction. As a result, the shielding portion 70 can reduce influence of an electromagnetic wave. Furthermore, the shielding portion 70 and the housing 20 contain a conductive material. As the shielding portion 70 and the first surface 21 of the housing 20 are arranged to be conductive, the shielding portion 70 and the housing 20 function as one conductive material. Therefore, influence of an electromagnetic wave on a component arranged in a space surrounded by the shielding portion 70 and the first surface 21 of the housing 20 is reduced.

As illustrated in FIG. 1, the first surface 21 is a bottom surface of the housing 20. As illustrated in FIG. 8, the bottom surface portion 612 of the storage 61 is separated from the first surface 21 of the housing 20 in the first direction D1. Therefore, in the cooling device 10 in which there is a gap between the radiator 60 and a bottom surface of the housing 20, the shielding portion 70 can block an electromagnetic wave entering from between the radiator 60 and the bottom surface of the housing 20. Note that the first surface 21 is not limited to a bottom surface. The first surface 21 may be, for example, a side surface.

As illustrated in FIG. 5, the pipe 62 allows liquid to flow along the Y-axis direction. The Y-axis direction corresponding to the second direction intersects the Z-axis direction corresponding to the first direction. That is, the second direction indicates a direction intersecting the first direction. The pipe 62 allows liquid to flow along the second direction. As illustrated in FIGS. 6 and 8, the shielding portion 70 performs shielding between the bottom surface portion 612 and the first surface 21. Therefore, even if there is a gap between the bottom surface portion 612 of the storage 61 and the first surface 21 of the housing 20, the shielding portion 70 can block an entering electromagnetic wave. Moreover, a distance by which the storage 61 is separated from the first surface 21 can be optionally set. As a result, the shielding portion 70 allows high degree of freedom in designing the storage 61. Note that the shielding portion 70 may be provided for both the storage 61A and the storage 61B. Further, the shielding portion 70 may also be provided for at least one of the storage 61A and the storage 61B.

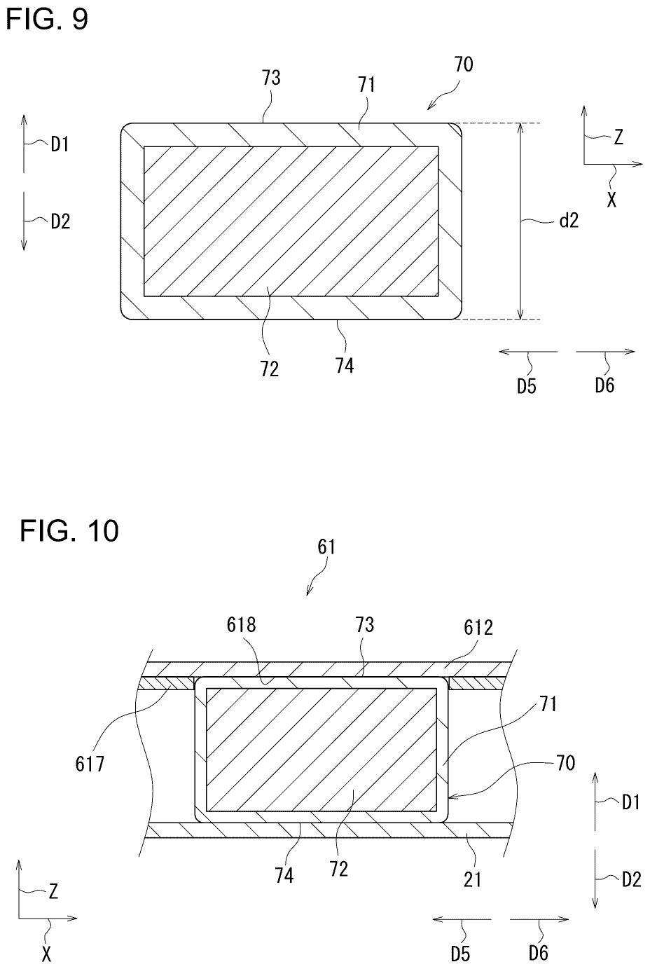

The shielding portion 70 will be described in detail with reference to FIGS. 9 and 10. FIG. 9 is a diagram illustrating a cross section of the shielding portion. FIG. 10 is a diagram illustrating a cross section taken along line X-X in FIG. 8.

As illustrated in FIGS. 6 to 9, the shielding portion 70 is formed in a rectangular parallelepiped shape. As illustrated in FIG. 9, a length of the shielding portion 70 in the Z-axis direction is d2. The length d2 is a length before the shielding portion 70 is arranged between the bottom surface portion 612 and the first surface 21. The length d1 in the first direction is smaller than the length d2 in the first direction of the shielding portion 70. The length d1 in the first direction is a length from the bottom surface portion 612 to the first surface 21. The length d2 in the first direction is a length in the first direction of the shielding portion 70. As illustrated in FIGS. 8 and 9, the length d2 in the first direction of the shielding portion 70 indicates a length in the Z-axis direction from a first contact portion 73 to a second contact portion 74. The first contact portion 73 is a portion in contact with the bottom surface portion 612 of the shielding portion 70 before being arranged between the bottom surface portion 612 and the first surface 21. The second contact portion 74 is a portion in contact with the first surface 21 of the shielding portion 70 before being arranged between the bottom surface portion 612 and the first surface 21. Therefore, the shielding portion 70 can ensure close contact with the bottom surface portion 612 of the storage 61, and can ensure close contact with the first surface 21 of the housing 20. As a result, the shielding portion 70 can reduce an electromagnetic wave entering from a gap between the bottom surface portion 612 of the storage 61 and the first surface 21 of the housing 20.

As illustrated in FIG. 9, the shielding portion 70 includes a first member 71 and a second member 72. The first member 71 has a cross section formed in a rectangular shape.

The first member 71 is a tubular member in which both end portions in the third direction D3 and the fourth direction D4 are opened. The first member 71 is made from a conductive material. The conductive material includes, for example, an electromagnetic wave shielding material such as copper, aluminum, nickel, or iron. An internal space of the first member 71 penetrates the first member 71 in the Y-axis direction. The second member 72 is arranged inside the first member 71.

The second member 72 is accommodated in the first member 71. The second member 72 is sealed in an internal space of the first member 71, for example. The second member 72 is made from a material different from that of the first member 71. The second member 72 is made from, for example, conductive plastic. Specifically, the material is metal powder, a carbon fine particle, and an aluminum-coated glass fiber. Therefore, since the shielding portion 70 can include the first member 71 and the second member 72 different from the first member 71, weight reduction can be achieved. As a result, the shielding portion 70 can reduce an entering electromagnetic wave while reducing increase in weight. Gas may be used as the second member 72. In a case where gas is used, the first member 71 has a structure capable of sealing the gas.

The second member 72 has, for example, thermal conductivity lower than that of the first member 71. The second member 72 is, for example, a sponge material containing a conductive material. However, thermal conductivity of the second member 72 is not limited to be lower than thermal conductivity of the first member 71 due to a structural change. Thermal conductivity of the second member 72 may be made lower than thermal conductivity of the first member 71 due to a change in a material. Therefore, the shielding portion 70 can reduce heat conducted from the radiator 60 side to the second component S2. As a result, temperature rise of the housing 20 is reduced. Further, as the second member 72 is made from a conductive material, a reflection loss function can also be provided between the second member 72 and the first member 71.

The second member 72 has elasticity. The second member 72 is, for example, a sponge material of a closed cell structure. However, the second member 72 is not limited to a sponge material of a closed cell structure. The second member 72 may have an elastic restoring force at least in the Z-axis direction after being arranged between the bottom surface portion 612 and the first surface 21. The second member 72 may be a sponge material of an open cell structure. Therefore, the second member 72 can enhance adhesion between the shielding portion 70 and the first component S1 and adhesion between the shielding portion 70 and the second component S2. The shielding portion 70 can reduce an entering electromagnetic wave. Note that the elastic restoring force is not necessarily a perfect restoring force, and may be an incomplete restoring force.

Cationic coating is applied to the storage 61. The cationic coating is coating treatment in which electrodeposition is performed with an object to be coated as a negative electrode and an electrode as a positive electrode. The storage 61 has a surface covered with a coating portion 617. The storage 61 has improved corrosion resistance. Note that, as illustrated in FIG. 10, cationic coating is not applied to a contact portion 618. The contact portion 618 is a part of the bottom surface portion 612 in contact with the first contact portion 73. That is, the storage 61 has the coating portion 617 around the contact portion 618 in contact with the shielding portion 70. Therefore, even if a coating material that is not conductive is used, the shielding portion 70 and the storage 61 can be conducted. That is, since the shielding portion 70 and the storage 61 are conducted, an electromagnetic wave is reflected between the shielding portion 70 and the storage 61. As a result, the shielding portion 70 can reduce an electromagnetic wave entering from between the shielding portion 70 and the radiator 60.

As illustrated in FIG. 8, a gap G in the Y-axis direction exists between the shielding portion 70 and the inner surface portion 614. However, since the shielding portion 70 and the storage 61 are conducted, in a case where the gap G is equal to or less than a predetermined range, an electromagnetic wave shield is formed in the gap G between the shielding portion 70 and the inner surface portion 614. A range of the gap G in which the electromagnetic wave shield can be formed is, for example, 4 mm or less.

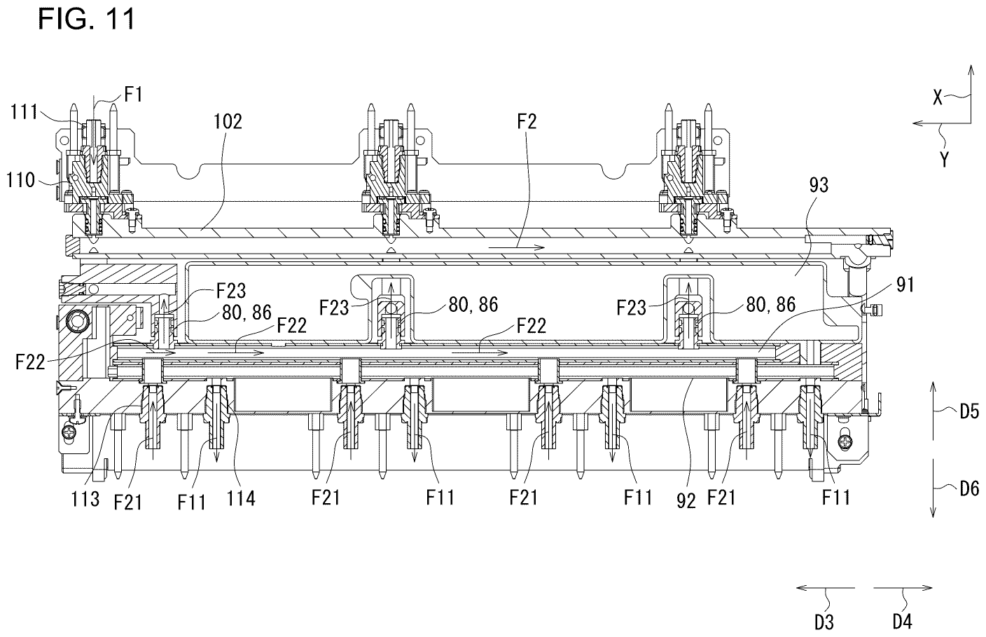

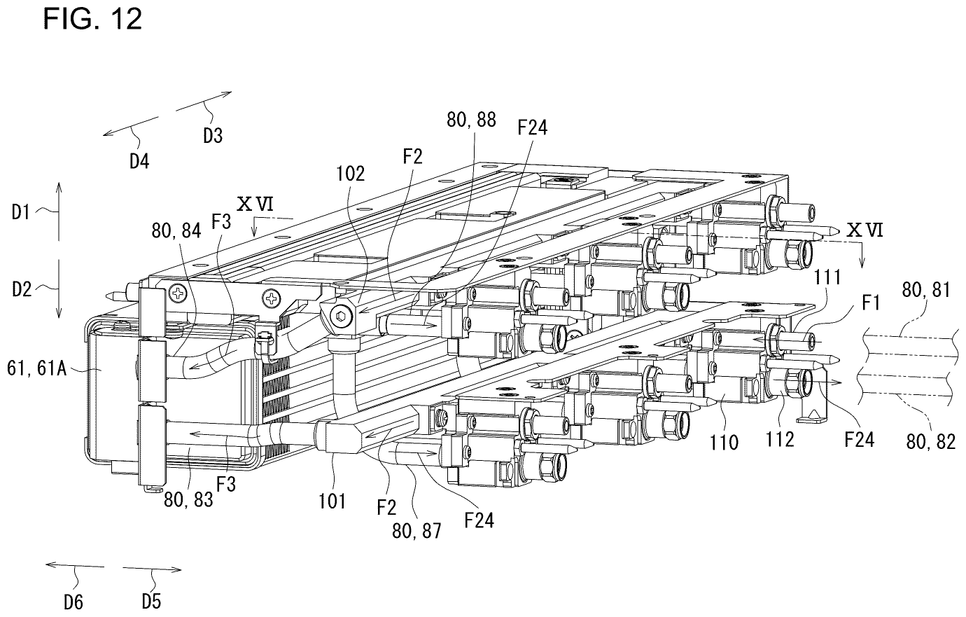

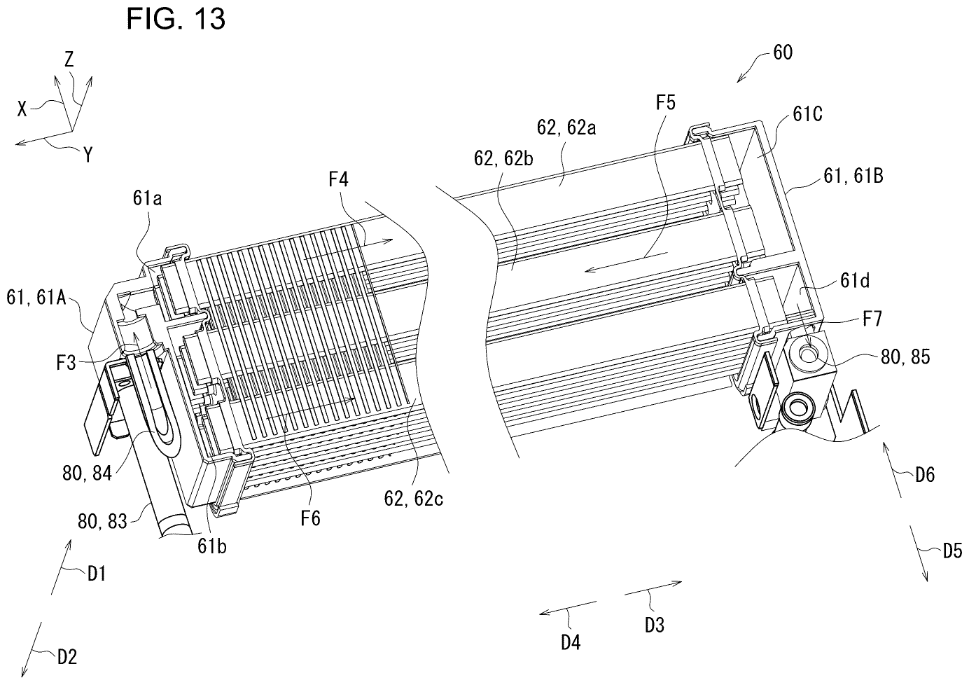

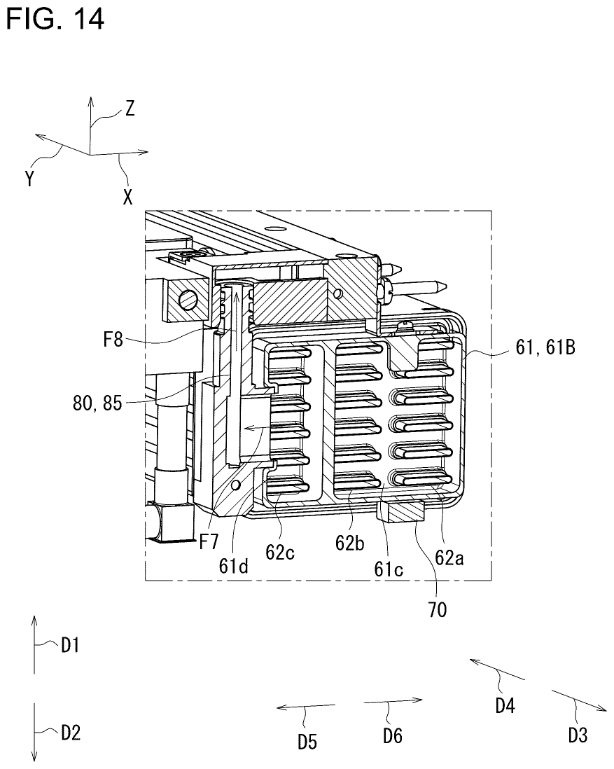

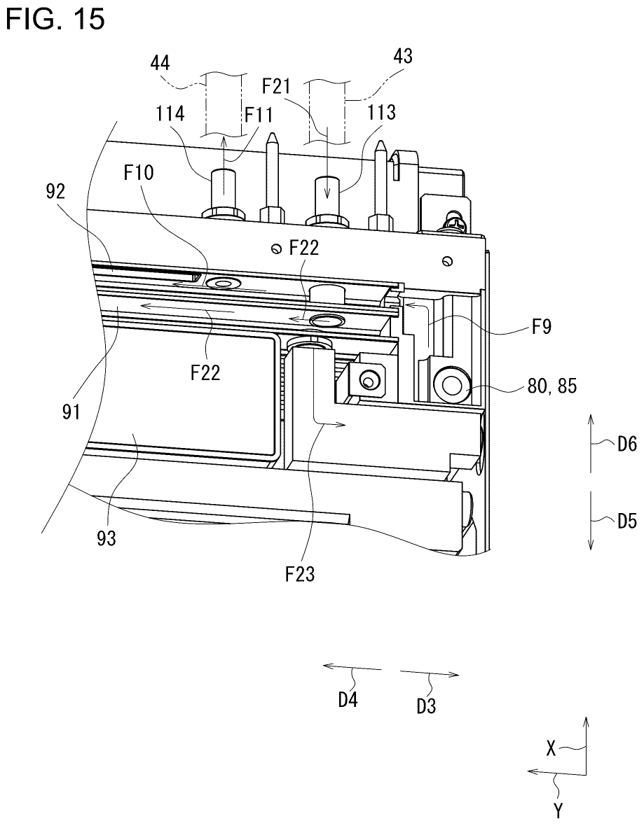

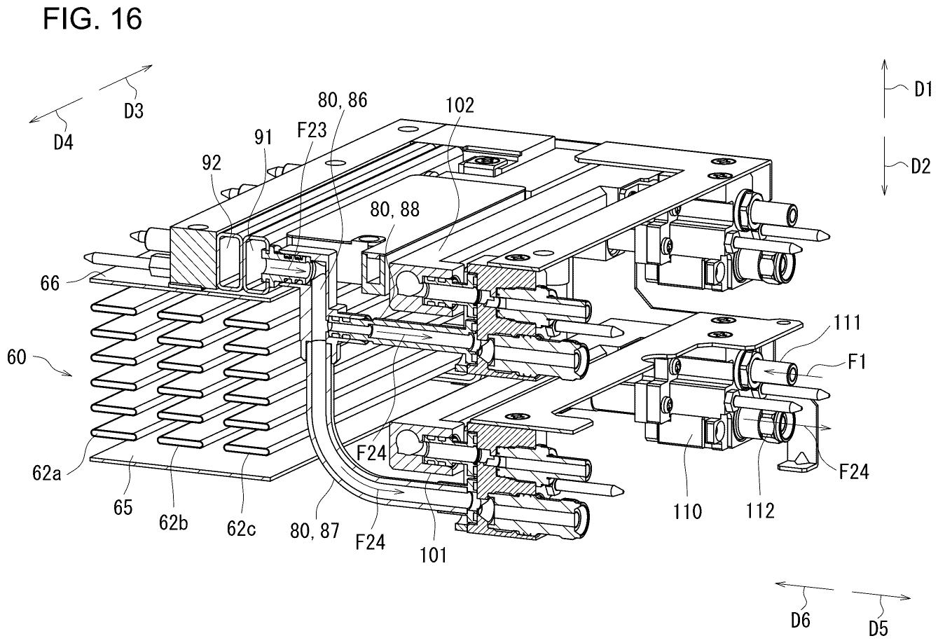

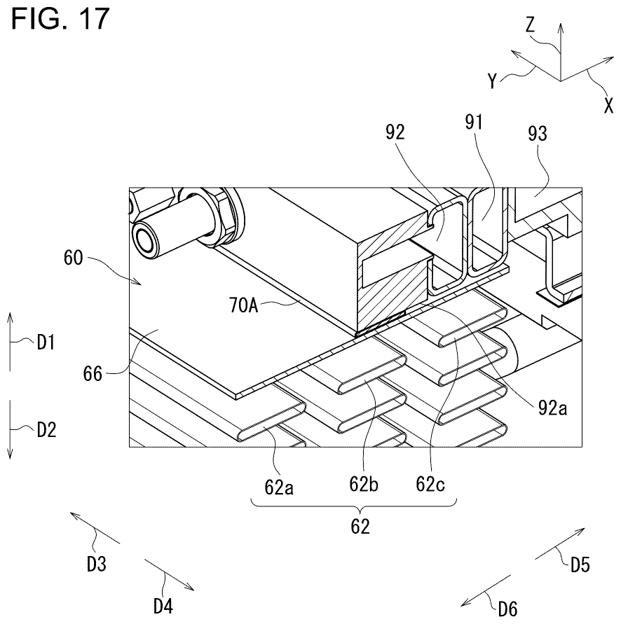

A circulation path of liquid will be described with reference to FIGS. 11 to 16. FIG. 11 is a diagram illustrating an internal flow path of a first accommodation portion 91, a second accommodation portion 92, and a third accommodation portion 93. FIG. 12 is a perspective view illustrating a connection portion on the cold plate 30 side of the radiator 60. FIG. 13 is a diagram illustrating an internal flow path of the radiator 60. FIG. 14 is a perspective view illustrating the inside of the storage 61. FIG. 15 is a diagram illustrating an internal flow path of the first accommodation portion 91, the second accommodation portion 92, and the third accommodation portion 93. FIG. 16 is a diagram illustrating a cross section taken along line XVI-XVI in FIG. 12.

As illustrated in FIGS. 11 and 16, the first accommodation portion 91, the second accommodation portion 92, and the third accommodation portion 93 are arranged on the first direction D1 side of the radiator 60. The first accommodation portion 91, the second accommodation portion 92, and the third accommodation portion 93 accommodate liquid.

The first accommodation portion 91 accommodates liquid sent from the liquid feeding device 40. The first accommodation portion 91 is formed in a rectangular parallelepiped shape. The first accommodation portion 91 extends along the third direction D3 and the fourth direction D4. As illustrated in FIG. 15, the first accommodation portion 91 is connected to the first pump 41 via the first coupling portion 43.

The second accommodation portion 92 accommodates liquid cooled by the radiator 60. The second accommodation portion 92 is formed in a rectangular parallelepiped shape. The second accommodation portion 92 is located between the first accommodation portion 91 and the liquid feeding device 40. As illustrated in FIG. 11, the second accommodation portion 92 extends along the third direction D3 and the fourth direction D4. The second accommodation portion 92 is connected to the second pump 42 via the second coupling portion 44.

The third accommodation portion 93 accommodates liquid cooled by the radiator 60. The third accommodation portion 93 is formed in a rectangular parallelepiped shape. The third accommodation portion 93 faces the second accommodation portion 92 in the sixth direction D6 and communicates with the second accommodation portion 92. The third accommodation portion 93 extends along the third direction D3 and the fourth direction D4. Since the third accommodation portion 93 is provided, a storage amount of a refrigerant can be increased. Therefore, even in a case where a refrigerant decreases in amount due to evaporation or the like, influence on cooling capacity can be reduced.

As illustrated in FIGS. 12 and 16, a first manifold 101 and a second manifold 102 are arranged between the radiator 60 and the cold plate 30. The first manifold 101 and the second manifold 102 accommodate liquid. The first manifold 101 and the second manifold 102 extend along the third direction D3 and the fourth direction D4. The first manifold 101 and the second manifold 102 are formed in a rectangular parallelepiped shape.

The first manifold 101 accommodates liquid send from the first cold plate 30A, the second cold plate 30B, and the third cold plate 30C of the first set cold plates 301. The first manifold 101 faces the radiator 60 in the sixth direction D6. The second manifold 102 accommodates liquid sent from the fourth cold plate 30D, the fifth cold plate 30E, and the sixth cold plate 30F of the second set cold plates 302. The second manifold 102 faces the third accommodation portion 93 in the sixth direction D6. The second manifold 102 is arranged in the first direction D1 of the first manifold 101.

As illustrated in FIG. 2, a pipe 81 and a pipe 82 extend from the cold plate 30 in the sixth direction D6. The pipe 81 and the pipe 82 are connected to a connector 110. Liquid after heat exchange flows from the cold plate 30 through the pipe 81 toward the connector 110. Liquid before heat exchange sent from the first accommodation portion 91 flows through the pipe 82 from the connector 110 toward the cold plate 30. Note that the connector 110 is provided on each of the first cold plate 30A, the second cold plate 30B, and the third cold plate 30C of the first set cold plates 301. Further, the connector 110 is provided on each of the fourth cold plate 30D, the fifth cold plate 30E, and the sixth cold plate 30F of the second set cold plates 302.

As illustrated in FIG. 12, the pipe 81 is coupled to a first connection portion 111. The pipe 82 is coupled to a second connection portion 112. A flow from the pipe 81 toward the first connection portion 111 is a flow F1. A flow from the second connection portion 112 toward the pipe 82 is a flow F24.

Liquid that finishes heat exchange with a heat generating component in the cold plate 30 flows into the first manifold 101 via the first connection portion 111. The liquid flows toward the storage 61A in the first manifold 101. A flow from a position on the third direction D3 side to a position on the fourth direction D4 side of the first manifold 101 is a flow F2. The liquid flows through a pipe 83 and flows into the storage 61A. As illustrated in FIGS. 7 and 12, the pipe 83 allows an end portion on the fourth direction D4 side of the first manifold 101 and an end portion on the fourth direction D4 side of the storage 61A to communicate with each other. A flow from an upstream side position to a downstream side position of the pipe 83 is a flow F3.

Similarly, liquid of the second set cold plates 302 flows into the second manifold 102. A flow from a position on the third direction D3 side to a position on the fourth direction D4 side of the second manifold 102 is the flow F2. The liquid flows through a pipe 84 and flows into the storage 61A. The pipe 84 allows an end portion on the fourth direction D4 side of the second manifold 102 to communicate with the storage 61A. A flow from an upstream side position to a downstream side position of the pipe 84 is the flow F3.

As illustrated in FIG. 13, the pipe 62 includes a first pipe 62a, a second pipe 62b, and a third pipe 62c. The pipe 62 may include, for example, a plurality of the first pipes 62a, a plurality of the second pipes 62b, and a plurality of the third pipes 62c. The first pipe 62a is located further on the sixth direction D6 side than the second pipe 62b. The second pipe 62b is located further on the sixth direction D6 side than the third pipe 62c.

The storage 61A includes a first chamber 61a and a second chamber 61b. The storage 61B includes a first chamber 61c and a second chamber 61d. As illustrated in FIGS. 13 and 14, the first pipe 62a allows the first chamber 61a and the first chamber 61c to communicate with each other. The second pipe 62b allows the second chamber 61b and the first chamber 61c to communicate with each other. The third pipe 62c allows the second chamber 61b and the second chamber 61d to communicate with each other.

As illustrated in FIG. 13, liquid flows into the first chamber 61a from the first direction D1 side pipe 83 and the second direction D2 side pipe 83. The liquid flows through the first pipe 62a. A flow from the first chamber 61a toward the first chamber 61c is a flow F4. The liquid flows into the first chamber 61c from the first pipe 62a. The liquid flows into the second pipe 62b from the first chamber 61c. The liquid flows through the second pipe 62b. A flow from the first chamber 61c toward the second chamber 61b is a flow F5. The liquid flows into the second chamber 61b from the second pipe 62b. The liquid flows into the third pipe 62c from the second chamber 61b. The liquid flows through the third pipe 62c. A flow from the second chamber 61b toward the second chamber 61d is a flow F6. The liquid flows from the third pipe 62c into the second chamber 61d. The liquid is cooled by heat exchange with outside air during the flow F4, the flow F5, and the flow F6. Therefore, with the first pipe 62a, the second pipe 62b, and the third pipe 62c, a total length of a pipe through which a refrigerant flows can be made large. As a result, cooling performance of the radiator 60 is improved.

As illustrated in FIG. 14, liquid flows into a pipe 85 from the second chamber 61d. A flow from the second chamber 61d toward the pipe 85 is a flow F7. The liquid flows through the pipe 85 toward the second accommodation portion 92. A flow from a position on the second direction D2 side to a position on the first direction D1 side of the pipe 85 is a flow F8.

As illustrated in FIG. 15, liquid flows into the second accommodation portion 92 from an opening of the pipe 85. A flow from the opening of the pipe 85 toward the second accommodation portion 92 is a flow F9. The liquid flows through the second accommodation portion 92 from a position on the third direction D3 side to a position on the fourth direction D4 side. A flow from a position on the third direction D3 side to a position on the fourth direction D4 side of the second accommodation portion 92 is a flow F10. The liquid flows into the second coupling portion 44 of the second pump 42 from the second accommodation portion 92 via a second connection portion 114. A flow from the second connection portion 114 toward the second coupling portion 44 is a flow F11.

Liquid is sent from the second pump 42 to the first pump 41. As illustrated in FIG. 3, the first pump 41 sends liquid to the first coupling portion 43. As illustrated in FIG. 15, the liquid flows into a first connection portion 113 via the first coupling portion 43. The first connection portion 113 is connected to the first accommodation portion 91. The first connection portion 113 penetrates the inside of the second accommodation portion 92. A flow from the first coupling portion 43 toward the first connection portion 113 is a flow F21.

As illustrated in FIG. 15, liquid flows through the first connection portion 113 and flows into the first accommodation portion 91. As illustrated in FIGS. 11 and 16, the first accommodation portion 91 and the connector 110 are coupled by a pipe 86. As illustrated in FIG. 11, in the first accommodation portion 91, a flow from an opening of the first connection portion 113 toward an opening of the pipe 86 is a flow F22.

The connector 110 is arranged for each of the cold plates 30. Specifically, as illustrated in FIG. 12, two sets of the connectors 110, each set including three of the connectors 110 adjacent in a direction along the third direction D3 and the fourth direction D4, are arranged in the first direction D1 and the second direction D2. Therefore, three of the pipes 86 extend in the fifth direction D5 from the first accommodation portion 91.

As illustrated in FIG. 11, the pipe 86 penetrates the third accommodation portion 93. Liquid stored in the first accommodation portion 91 flows into the pipe 86. A flow from the first accommodation portion 91 toward the connector 110 is a flow F23. As illustrated in FIG. 16, the pipe 86 branches into a pipe 87 located on the second direction D2 side and the pipe 87 located on the first direction D1 side in an intermediate section. A flow from the pipe 86 toward the pipe 87 is the flow F24. The pipe 87 located on the second direction D2 side is connected to the connector 110 connected to the first cold plate 30A, the second cold plate 30B, and the third cold plate 30C. Liquid that reaches the connector 110 flows into the pipe 82 via the second connection portion 112. Note that the pipe 87 located on the first direction D1 side is connected to the connector 110 connected to the fourth cold plate 30D, the fifth cold plate 30E, and the sixth cold plate 30F.

FIG. 17 is another diagram illustrating a shielding portion 70A according to a first variation of the example embodiment of the present disclosure. The shielding portion 70A of the first variation is different from the shielding portion 70 of the present example embodiment in that the shielding portion 70A is arranged on the first direction D1 side of the radiator 60.

As illustrated in FIG. 17, the second accommodation portion 92 is arranged on the first direction D1 side of the radiator 60. The second accommodation portion 92 accommodates liquid that is before being sent to the liquid feeding device 40. The second accommodation portion 92 faces the top plate 66 of the radiator 60 in the second direction D2. The second accommodation portion 92 has a bottom surface 92a. The bottom surface 92a is separated from the top plate 66 in the first direction D1. The second accommodation portion 92 is different from the radiator 60. The second accommodation portion 92 corresponds to an example of the “second component S2”. That is, the second component S2 includes the second accommodation portion 92 that accommodates liquid.

The shielding portion 70A is a shielding member that blocks intrusion of an electromagnetic wave. The shielding portion 70A has the same configuration as the shielding portion 70 except for an outer shape. A length in the Z-axis direction between the radiator 60 and the second accommodation portion 92 is smaller than a length in the Z-axis direction of the shielding portion 70A before being arranged between the radiator 60 and the second accommodation portion 92. The shielding portion 70A is arranged between the second accommodation portion 92 and the radiator 60. That is, the shielding portion 70A performs shielding between the top plate 66 and the bottom surface 92a. Therefore, the shielding portion 70A can block an electromagnetic wave entering from between the radiator 60 and the second accommodation portion 92. As a result, in the cooling device 10 using the radiator 60 in which the second accommodation portion 92 is arranged, the shielding portion 70A can reduce influence of an electromagnetic wave. Further, since cooling air leaking from between the radiator 60 and the second accommodation portion 92 can be reduced in amount, cooling efficiency of the radiator 60 can be maintained high.

The present example embodiment and the variation are described above with reference to the drawings. However, the present disclosure is not limited to the above example embodiment and variation, and can be implemented in various modes without departing from the gist of the present disclosure. Further, a plurality of constituent elements disclosed in the above example embodiment and variation can be appropriately modified.

Further, the drawings schematically illustrate each constituent element mainly in order to facilitate understanding of the disclosure, and the thickness, length, number, interval, and the like of the illustrated constituent elements may be different from the actual ones for convenience of creation of the drawings. Further, the configuration of each constituent element illustrated in the above example embodiment is an example and is not particularly limited, and it goes without saying that various modifications can be made without substantially departing from the effects of the present disclosure.

Note that the techniques according to example embodiments of the present invention can have any of the configurations below.

(1) A cooling device including a first component to cool a heat generating component, a second component different from the first component, and a shielding portion to perform shielding between the first component and the second component, in which the shielding portion includes a conductive material.

(2) The cooling device according to (1), in which the first component includes a heat exchanger, and the shielding portion performs shielding between the heat exchanger and the second component.

(3) The cooling device according to (1) or (2), in which the second component includes a housing surrounding a periphery of the heat exchanger, and the housing includes a first surface and a second surface opposing the first surface. The shielding portion performs shielding between the heat exchanger and the first surface opposing the heat exchanger in a first direction, and the first direction indicates a direction in which the first surface and the second surface oppose each other.

(4) The cooling device according to (3), in which the first surface is a bottom surface of the housing.

(5) The cooling device according to any of (2) to (4), in which the heat exchanger includes a storage to store liquid, and a pipe through which the refrigerant flows. The storage includes a top surface portion and a bottom surface portion opposing the top surface portion in the first direction, and the shielding portion performs shielding between the bottom surface portion and the first surface.

(6) The cooling device according to (5), in which a length in the first direction from the bottom surface portion to the first surface is less than a length in the first direction of the shielding portion, and a length in the first direction of the shielding portion indicates a length from a first contact portion in contact with the bottom surface portion of the shielding portion to a second contact portion in contact with the first surface of the shielding portion before the shielding portion is arranged between the bottom surface portion and the first surface.

(7) The cooling device according to (5) or (6), in which the storage includes a conductive material and a coating portion around a contact portion in contact with the shielding portion.

(8) The cooling device according to any of (3) to (7), in which the second component includes an accommodation portion to accommodate the liquid, the accommodation portion is on the second surface side in the first direction of the heat exchanger, and the shielding portion is between the accommodation portion and the heat exchanger.

(9) The cooling device according to any of (1) to (8), in which the shielding portion includes a first portion made from the conductive material and a second portion made from a material different from a material of the first member.

(10) The cooling device according to (9), in which the first portion includes the second portion in an interior thereof, and a thermal conductivity lower of the second portion is lower than that of the first portion.

(11) The cooling device according to (9) or (10), in which the second portion has elasticity.

(12) The cooling device according to (5), further including a cooling assembly to cool the heat generating component with the refrigerant, in which the cooling assembly is on one side in a third direction with respect to the heat exchanger, and the third direction intersects the first direction and a second direction in which the refrigerant flows through the pipe.

(13) The cooling device according to (12), further including a blowing assembly to send air to the heat exchanger, in which the blowing assembly is located on another side in the third direction with respect to the heat exchanger.

(14) The cooling device according to claim (12) or (14), further including a liquid feeding assembly to cause the refrigerant to flow, in which the liquid feeding assembly is located on another side in the third direction with respect to the heat exchanger.

Example embodiments of the present disclosure are applicable to, for example, cooling devices.

Features of the above-described example embodiments and the modifications thereof may be combined appropriately as long as no conflict arises.

While preferred example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a first component to cool a heat generating component;
a second component different from the first component; and
a shielding portion to perform shielding between the first component and the second component; wherein
the shielding portion includes a conductive material.

2. The cooling device according to claim 1, wherein
the first component includes a heat exchanger; and
the shielding portion performs shielding between the heat exchanger and the second component.

3. The cooling device according to claim 2, wherein
the second component includes a housing surrounding a periphery of the heat exchanger,
the housing includes:
a first surface; and
a second surface opposing the first surface;
the shielding portion performs shielding between the heat exchanger and the first surface opposing the heat exchanger in a first direction; and
the first direction indicates a direction in which the first surface and the second surface oppose each other.

4. The cooling device according to claim 3, wherein the first surface is a bottom surface of the housing.

5. The cooling device according to claim 4, wherein
the heat exchanger includes:
a storage that stores a refrigerant; and
a pipe through which the liquid flows;
the storage includes:
a top surface portion; and
a bottom surface portion facing the top surface portion in the first direction; and
the shielding portion performs shielding between the bottom surface portion and the first surface.

6. The cooling device according to claim 5, wherein
a length in the first direction from the bottom surface portion to the first surface is less than a length in the first direction of the shielding portion; and
a length in the first direction of the shielding portion indicates a length from a first contact portion in contact with the bottom surface portion of the shielding portion to a second contact portion in contact with the first surface of the shielding portion before the shielding portion is arranged between the bottom surface portion and the first surface.

7. The cooling device according to claim 5, wherein the storage includes a conductive material and a coating portion around a contact portion in contact with the shielding portion.

8. The cooling device according to claim 3, wherein
the second component includes an accommodation portion to accommodate the liquid;
the accommodation portion is on the second surface side in the first direction of the heat exchanger; and
the shielding portion is between the accommodation portion and the heat exchanger.

9. The cooling device according to claim 1, wherein
the shielding portion includes:
a first portion made from the conductive material; and
a second portion made from a material different from a material of the first portion.

10. The cooling device according to claim 9, wherein
the first portion includes the second portion in an interior thereof; and
a thermal conductivity of the second portion is lower than that of the first portion.

11. The cooling device according to claim 9, wherein the second portion has elasticity.

12. The cooling device according to claim 5, further comprising:
a cooling assembly to cool the heat generating component with the refrigerant; wherein
the cooling assembly is on one side in a third direction with respect to the heat exchanger; and
the third direction intersects the first direction and a second direction in which the refrigerant flows through the pipe.

13. The cooling device according to claim 12, further comprising:
a blowing assembly to send air to the heat exchanger; wherein
the blowing assembly is located on another side in the third direction with respect to the heat exchanger.

14. The cooling device according to claim 12, further comprising:
a liquid feeding assembly to cause the refrigerant to flow; wherein
the liquid feeding assembly is located on another side in the third direction with respect to the heat exchanger.
